(19) United States
(12) Patent Application Publication
(10) Pub. No.: US 2009/0265123 A1
(43) Pub. Date: Oct. 22, 2009

(54) BACK-UP DATA DELIVERY DEVICE FOR AN UNPOWERED UTILITY METER AND METHOD OF USING THE SAME

(75) Inventors: Lawrence Russell Porter, Dallas, TX (US); John Paul King, Allen, TX (US)

Correspondence Address: HITT GAINES P.C., P.O. BOX 832570, RICHARDSON, TX, 75083, US

(73) Assignee: TransData, Inc., Carrollton, TX (US)

(21) Appl. No.: 12/105,001

(22) Filed: Apr. 17, 2008

(51) Int. Cl. G06F 17/40; G01R 21/00

(52) U.S. Cl. 702/62; 702/187

(57) ABSTRACT

Introduced is a utility meter data collection device for the collection of metered data when primary power to the utility meter is unavailable. In one embodiment the device includes (1) a back-up battery configured to provide power to communicate metered data when primary power to a utility meter is unavailable; (2) a communication apparatus with a detector for detecting an interrogation signal; and (3) a micro-processor, coupled to the back-up battery and the communication apparatus, to determine if the interrogation signal is detected and, if detected, switching to an active mode to communicate the metered data.

### TECHNICAL FIELD

The invention is directed, in general, to utility meters and, more specifically, to a device that enables a utility meter to deliver collected meter data when primary power to the utility meter is unavailable.

### BACKGROUND

When primary power to a utility meter goes out or is shut off, the utility company can not read the meter using normal procedures. It should be noted that there are a number of reasons why primary power to a utility meter might become unavailable. The most obvious reason is the case of a natural disaster causing a general power outage. Such a natural disaster could range from a hurricane, such as Katrina where the electrical power outage was extensive and took a considerable amount of time before service was restored, to a West Texas thunderstorm where the electrical power outage is much smaller in geographic scope. A power outage may affect only a small community or it may affect several states. In any case, after the natural disaster is concluded and normal activity is resumed, the various utility companies involved will be trying to resume normal operations, even if electrical power has not yet been restored to all of its customers.

Normal operations for the utility company will include getting their customers billed on a timely basis. This means that utility meters must be read so the customers receive an accurate billing statement on a timely basis. The people reading the meters may have to read meters in areas where power has not yet been restored. A device that enables meters to be read when primary power to the meter fails is needed.

In other cases, electrical power may have been disconnected deliberately by the customer for legitimate reasons. For example, people that own seasonal or vacation homes frequently disconnect power to the home when they leave at the conclusion of the seasonal activities in order to conserve power as well as for safety reasons to reduce the risk of starting an electrical fire if something shorts out or an appliance malfunctions. Fair grounds and similar venues also may shut down or disconnect power when the venue is not in use. In such cases, meters still need to be read and statements furnished to customers.

If primary power is off, prior art provided for the typical meter to be dismounted and plugged into an apparatus carried by the person reading the meter. This separate apparatus would provide temporary power to the meter so collected metered data could be communicated to the meter reader. Even if the meter does not have to be dismounted, power from some external source would still have to be applied to the meter in order for it to be read.

Accordingly, what is needed in the art is a device that permits a utility meter to be read when its primary power source is not available.

### SUMMARY

To address the above-discussed deficiencies of the prior art, one aspect of the invention provides, in one embodiment, (1) a back-up battery configured to provide power to communicate metered data when primary power to a utility meter is unavailable; (2) a communication apparatus with a detector for detecting an interrogation signal; and (3) a micro-processor, coupled to the back-up battery and the communication apparatus, the micro-processor determining if an interrogation signal is detected and, if detected, switching to an active mode to communicate the metered data.

The present invention also provides several embodiments of methods of manufacturing the device as well as methods of using the device.

The foregoing has outlined certain aspects and embodiments of the invention so that those skilled in the pertinent art may better understand the detailed description of the invention that follows. Additional aspects and embodiments will be described hereinafter that form the subject of the claims of the invention. Those skilled in the pertinent art should appreciate that they can readily use the disclosed aspects and embodiments as a basis for designing or modifying other structures for carrying out the same purposes of the invention. Those skilled in the pertinent art should also realize that such equivalent constructions do not depart from the scope of the invention.

### BRIEF DESCRIPTION OF THE DRAWINGS

For a more complete understanding of the invention, reference is now made to the following descriptions taken in conjunction with the accompanying drawings, in which:

FIG. 1 illustrates a block diagram of a utility meter that includes a data delivery device constructed in accordance with the present invention to use when communicating collected meter data when primary power to the meter is unavailable;

FIG. 2 illustrates a flow chart explaining the operation of a data delivery device, constructed in accordance with the present invention, for communicating collected meter data from a utility meter when primary power to the meter is unavailable; and

FIG. 3 illustrates a typical utility meter that includes a meter reading device constructed in accordance with the present invention.

### DETAILED DESCRIPTION OF CERTAIN ASPECTS AND EMBODIMENTS

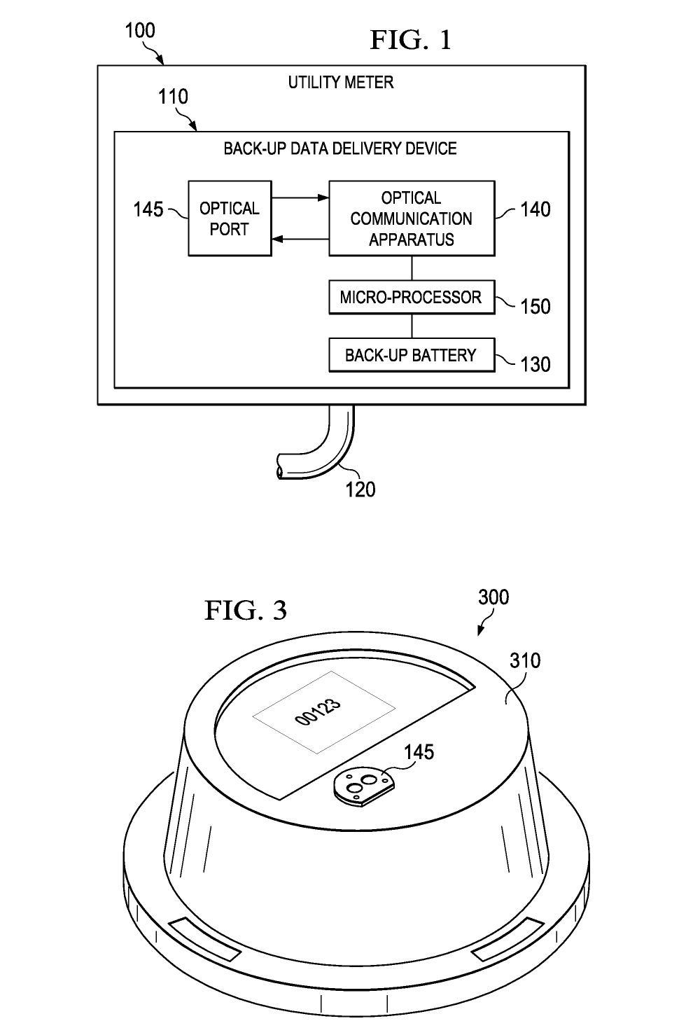

Turning initially to FIG. 1, illustrated is a block diagram of a utility meter 100 that includes a back-up data delivery device 110, constructed in accordance with the present invention, to communicate collected meter data when primary power 120 to the meter is unavailable. The present invention addresses the problem of how to read a utility meter 100 when primary power 120 to the meter 100 is not available by providing back-up power with a back-up battery 130. The back-up power to be provided must be sufficient to communicate collected metered data although it may not be enough to operate the meter. That is, in order for the meter to operate normally, primary power to the meter must be restored.

The data delivery device 110, when constructed in accordance with the present invention, provides for the utility meter 100 to have, or have associated with it, a communication apparatus 140 that includes a transmitter for transmitting data and a receiver for receiving data. In the illustrated embodiment, an optical transmitter and an optical receiver is used. That is, the illustrated communication apparatus 140 includes a detector that is an optical port 145 for the communication of collected metered data to a meter reader or a meter reading device. In most cases the collected metered data will be communicated directly to the person reading the meter 100 via the optical port 145. In other cases, the optical port 145 will respond to an interrogation signal and the data delivery device 110 will provide sufficient power to activate the meter 100 so that the collected meter data can be visually communicated to the meter reader. Although the illustrated embodiment shows an optical port 145 for reading the meter 100, the meter 100 data can also be collected using other types of a communication apparatus known to those of ordinary skill in the pertinent art and be within the intended scope of the present invention. Such other types of communication apparatus include RF devices, serial port devices, magnetic devices, other battery powered devices, all of which are within the intended scope of the present invention.

The data delivery device 110, when constructed in accordance with the present invention, includes a micro-processor 150 coupled to the back-up battery 130 and communication apparatus 140. Prior art provided that, when primary power 120 to the meter 100 was unavailable, the utility meter 100 could only be read by either removing the meter 100 and plugging it into a device that provided sufficient power so that the meter 100 could be read or by applying power from a separate external source to the meter 100, such as a separate battery powered device.

The present invention addresses the problem of reading a utility meter 100 when primary power 120 to the meter 100 is not available. As noted previously, there are a number of reasons why primary power 120 may become unavailable, ranging from a natural disaster, such as a hurricane or a flood, to the deliberate disconnection of power where, for example, the owner of a vacation home disconnects electrical power during the off-season in order to save on utility bills. The present invention addresses these situations by permitting the utility meter 100 to be read without going through the labor intensive and time consuming inconvenience of either removing the meter 100 to provide power or by applying an alternate external source of power to the meter 100.

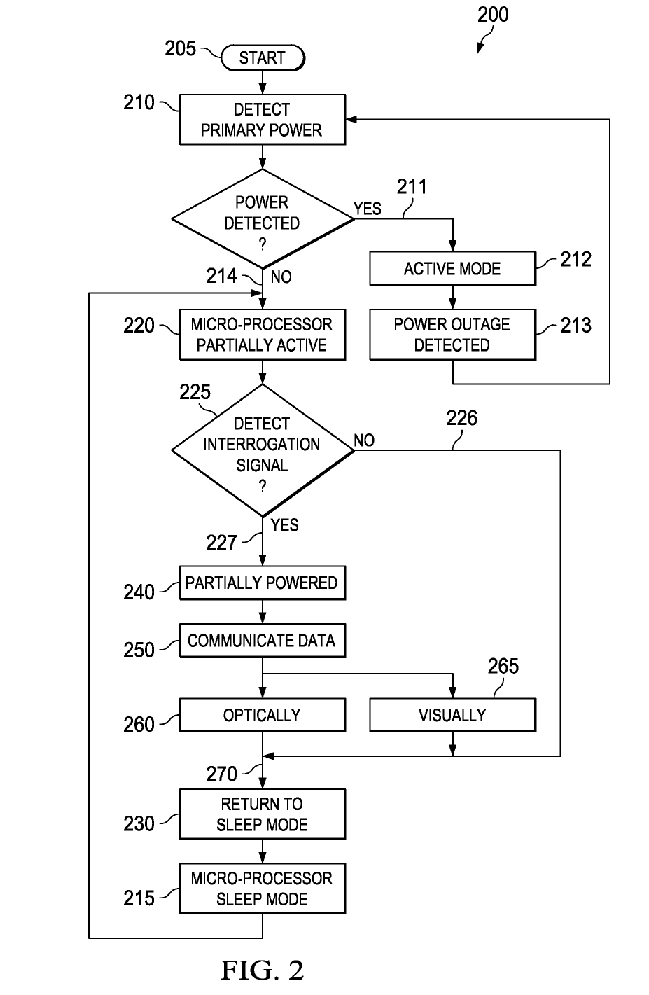

Referring to FIG. 2, illustrated is a flow chart explaining the operation 200 of a data delivery device 110 constructed in accordance with the present invention. The operation commences with a start step 205. In a detect primary power step 210, a determination is made as to whether primary power 120 to the utility meter 100 is available. If primary power is detected 211, the data delivery device goes into a normal active mode 212, which mode it maintains until a power outage is detected 213.

When a power outage is detected 213, the device starts another detect primary power step 210. At this time, if primary power is not detected 214, the micro-processor 150 becomes partially active 220. While partially active 220, the device 110 checks to see if an interrogation signal is detected in a detect interrogation signal step 225. If an interrogation signal is not detected 226, one embodiment of the invention provides for the microprocessor to return to a sleep mode 215 in a return to sleep mode step 230. As long as primary power 120 remains unavailable, this embodiment of the invention provides for the micro-processor 150 to cycle between the sleep mode 215 and the partially active 220 mode and periodically perform a detect interrogation signal step 225. By periodically checking for the detection of an interrogation signal, battery life will be conserved because the micro-processor will remains in a sleep mode 215 for the majority of the time. In one embodiment, the micro-processor goes to the partially active mode 220 every ten seconds, although any period of time could be used and be within the intended scope of the invention.

If an interrogation signal is detected 227, the micro-processor goes to an on-state, in a partial power-on step 240, and switches to a mode for the back-up battery on to provide sufficient power to communicate collected meter data in a communicate data step 250. Various embodiments of the invention provide for the collected meter data to be communicated in various ways. In the illustrated embodiment 200, collected meter data can be communicated either by optically 260 or visually 265 by way of a display device on the meter. After the collected meter data is communicated, the micro-processor returns 270 to the resting or sleep mode 215. The process 200 will be restarted each time the micro-processor no longer detects the absence of primary power to the meter.

An attractive embodiment of the invention provides for the back-up battery 130 to be a lithium 1000 milliamp hour battery 130. This embodiment permits the back-up battery to last for several years when the micro-processor is in a sleep or inactive status. Of course, those skilled in the pertinent art will readily understand that any battery 130 can be used and be within the intended scope of the present invention. In one embodiment of the invention, the micro-processor is an Analog Devices ADE7169 OR ADE5169 Energy Measurement IC®/micro-processor, although, as known by those skilled in the relevant art, any micro-processor can be used and be within the intended scope of the present invention.

Turning now to FIG. 3, illustrated is a typical utility meter 300 that can include a meter reading device constructed in accordance with the present invention. The meter 300 is typical in that it has a transparent or glass cover 310 over the various components that make up the metering device. The meter reading device constructed in accordance with the present invention is located under the cover 310. This illustrates an embodiment of the present invention where the device is integrated into the meter 300. The back-up battery, micro-processor and the majority of the parts of the optical communication device are under the cover 310 and are not visible. However, the optical port 145 is visible and is shown. When a meter reader wants to read the meter 300, an optical interrogation signal is sent to the meter 300 via this optical port 145 and, if primary power is not available, the meter 300 can still be read in a normal fashion because the meter detects the interrogation signal and uses its internal battery power to switch to a partially powered on state to enable the meter 300 to be read.

The meter reading device described herein can be used with any meter, although it most probably would be used with meters that collect usage data of electricity, natural gas and water. It could be used with any other meter that measures flow or usage. For example it could be used with a meter that measures the flow of oil through a pipeline and be within the intended scope of the present invention.

Several embodiments of methods of manufacturing and using the present invention are also claimed herein. These embodiments will be readily apparent to those skilled in the pertinent art from the disclosure set forth above.

Those skilled in the art to which the invention relates will appreciate that other and further additions, deletions, substitutions and modifications may be made to the described embodiments without departing from the scope of the invention.

What is claimed is:

1. A utility meter data collection device, comprising:
a back-up battery configured to provide power to communicate metered data when primary power to said utility meter is unavailable;
a communication apparatus having a detector for detecting an interrogation signal; and
a micro-processor, coupled to said back-up battery and said communication apparatus, to determine if said interrogation signal is detected and, if detected, switching to a mode to communicate said metered data.

2. The device as recited in claim 1 wherein a normal state for said micro-processor when no primary power is applied is a resting mode, said micro-processor periodically switching from a resting mode to a partially active mode to determine if said interrogation signal is detected.

3. The device as recited in claim 2 wherein said micro-processor switches to a partially active mode about every ten seconds.

4. The device as recited in claim 1 wherein utility meter includes said battery, said communication apparatus and said micro-processor as integral components.

5. The device as recited in claim 1 wherein said utility meter collects metered data regarding usage from the group consisting of:
electricity;
natural gas; and
water.

6. The device as recited in claim 1 wherein said metered data is communicated via said communication apparatus.

7. The device as recited in claim 1 wherein said metered data is communicated via a device selected from the group comprising:
a visual display device;
a radio frequency communications device;
a serial communication device; or
an optical communication device.

8. A method of manufacturing a utility meter data collection device, comprising:
providing a back-up battery configured to provide power to communicate metered data when primary power to said utility meter is unavailable;
providing a communication apparatus having a detector for detecting an interrogation signal; and
providing a micro-processor, coupled to said back-up battery and said communication apparatus, to determine if said interrogation signal is detected and, if detected, switching to a mode to communicate said metered data.

9. The method as recited in claim 8 wherein a normal state for said micro-processor when no primary power is applied is a resting mode, said micro-processor periodically switching from a resting mode to a partially active mode to determine if said interrogation signal is detected.

10. The method as recited in claim 9 wherein said micro-processor switches to a partially active mode about every ten seconds.

11. The method as recited in claim 8 wherein utility meter includes said battery, said communication apparatus and said micro-processor as integral components.

12. The method as recited in claim 8 wherein said utility meter collects metered data usage from the group consisting of:
electricity;
natural gas; and
water.

13. The method as recited in claim 8 wherein said metered data is communicated via said communication apparatus.

14. The method as recited in claim 8 wherein said metered data is communicated via a device selected from the group comprising:
a visual display device;
a radio frequency communications device;
a serial communication device; or
an optical communication device.

15. A method of using a utility meter data collection device, comprising:
causing a back-up battery to be configured to provide power to communicate metered data when primary power to said utility meter is unavailable;
causing a communication apparatus having a detector for detecting an interrogation signal; and
causing a micro-processor, coupled to said back-up battery and said communication apparatus, to determine if said interrogation signal is detected and, if detected, switching to a mode to communicate said metered data.

16. The method as recited in claim 15 wherein a normal state for said micro-processor is a resting mode, said micro-processor when insufficient primary power is applied periodically switching from a resting mode to a partially active mode to determine if said interrogation signal is detected.

17. The method as recited in claim 16 wherein said micro-processor switches to a partially active mode about every ten seconds.

18. The method as recited in claim 15 wherein said utility meter includes said battery, said communication apparatus and said micro-processor as integral components.

19. The method as recited in claim 15 wherein said metered data is communicated via said communication apparatus.

20. The method as recited in claim 15 wherein said metered communicated via a device selected from the group comprising:
a visual display device;
a radio frequency communications device;
a serial communication device; or
an optical communication device.
